(19) United States
(12) Patent Application Publication
(10) Pub. No.: US 2011/0119544 A1
(43) Pub. Date: May 19, 2011

(54) User Guided Short Correction And Schematic Fix Visualization

(76) Inventors: William Matthew Hogan, Lake Oswego, OR (US); MacDonald Hall Jackson, III, Corvallis, OR (US)

(21) Appl. No.: 12/797,602

(22) Filed: Jun. 9, 2010

Related U.S. Application Data
(60) Provisional application No. 61/185,584, filed on Jun. 9, 2009.

(51) Int. Cl. G06F 11/273; G01R 31/28

(52) U.S. Cl. 714/734; 714/E11.17

(57) ABSTRACT

Techniques for assisting a designer in correcting discrepancies identified in layout design data. A user interface may be provided listing identified shorts and relevant information related to those shorts. Still further, the user interface may allow a designer to selectively choose a subset of the identified shorts, and to designate or otherwise provide correction data for use to correct the shorts before performing a short isolation process on the selected shorts. Alternately or additionally a user interface may provide a designer with graphical images showing the correction that should be made by a designer to address an identified discrepancy in layout design data.

### RELATED APPLICATIONS

This application claims priority under 35 U.S.C. §119 to U.S. Provisional Patent Application No. 61/185,584, entitled “User Guided Short Correction And Schematic Fix Visualization,” filed Jun. 9, 2009, and naming William Matthew Hogan et al. as inventors, which application is incorporated entirely herein by reference.

### FIELD OF THE INVENTION

The present invention is directed to the correction of discrepancies in layout design data for electronic devices. Various aspects of the invention may be particularly useful for allowing a designer to selectively correct shorts in a layout design or visualize inaccurate connections.

### BACKGROUND OF THE INVENTION

Correction of discrepancies in layout design data can be extremely tedious for a designer to correct. For example, with conventional electronic design automation tools, a short isolation operation will detect all of the shorts in the layout design data at one time. To optimize design time, a designer must therefore attempt to fix or otherwise correct every identified short before performing a subsequent short isolation operation. Since many shorts are complicated and cannot be corrected on an initial pass, this arrangement makes short correction very difficult. Still other conventional design automation tools may identify high-level discrepancies in an extracted schematic design, and then provide a designer with text listing of the discrepancies. For example, some sophisticated layout-versus-schematic processes may provide a designer with text “hints” for correcting discrepancies. Even with these text “hints,” however, it may be difficult for a designer to easily understand the nature of a discrepancy and appreciate the proper design correction to remove that discrepancy.

### BRIEF SUMMARY OF THE INVENTION

Aspects of the invention relate to techniques for assisting a designer in correcting discrepancies identified in layout design data. For example, some implementations of the invention may provide a user interface listing identified shorts and relevant information related to those shorts. Still further, with some examples of the invention, the user interface may allow to selectively choose a subset of the identified shorts, and to select or otherwise provide correction data for use to correct the shorts before performing a short isolation process on the selected shorts. Still other implementations of the invention may alternately or additionally provide a designer with graphical images showing the correction that should be made by a designer to address an identified discrepancy in layout design data.

### BRIEF DESCRIPTION OF THE DRAWINGS

FIG. 1 illustrates an example of a computer operating environment that may be employed to implement various embodiments of the invention.

FIG. 2 illustrates an example of a multi-core processor unit that may be employed in the computer operating environment illustrated in FIG. 1.

FIG. 3 illustrates an example of a layout design analysis tool system that may be employed to implement various embodiments of the invention.

FIG. 4 illustrates an example of a user-guided short correction tool that may be implemented according to various examples of the invention.

FIG. 5 illustrates an example of a user interface includes for displaying information relating to shorts identified in layout design data that may be provided according to various examples of the invention.

FIG. 6A illustrates an example of an image that may be provided to graphically show a connection in an original schematic design corresponding to a discrepancy identified in an extracted schematic design according to various examples of the invention.

FIG. 6B illustrates an example of an image that may be provided to graphically show the discrepant connection in the extracted schematic design according to various implementations of the invention.

FIG. 6C illustrates an example of an image that may be provided to graphically show how the layout design data should be corrected so that the extracted schematic design properly corresponds with the original schematic design according to various examples of the invention.

### DETAILED DESCRIPTION OF THE INVENTION

### Exemplary Operating Environment

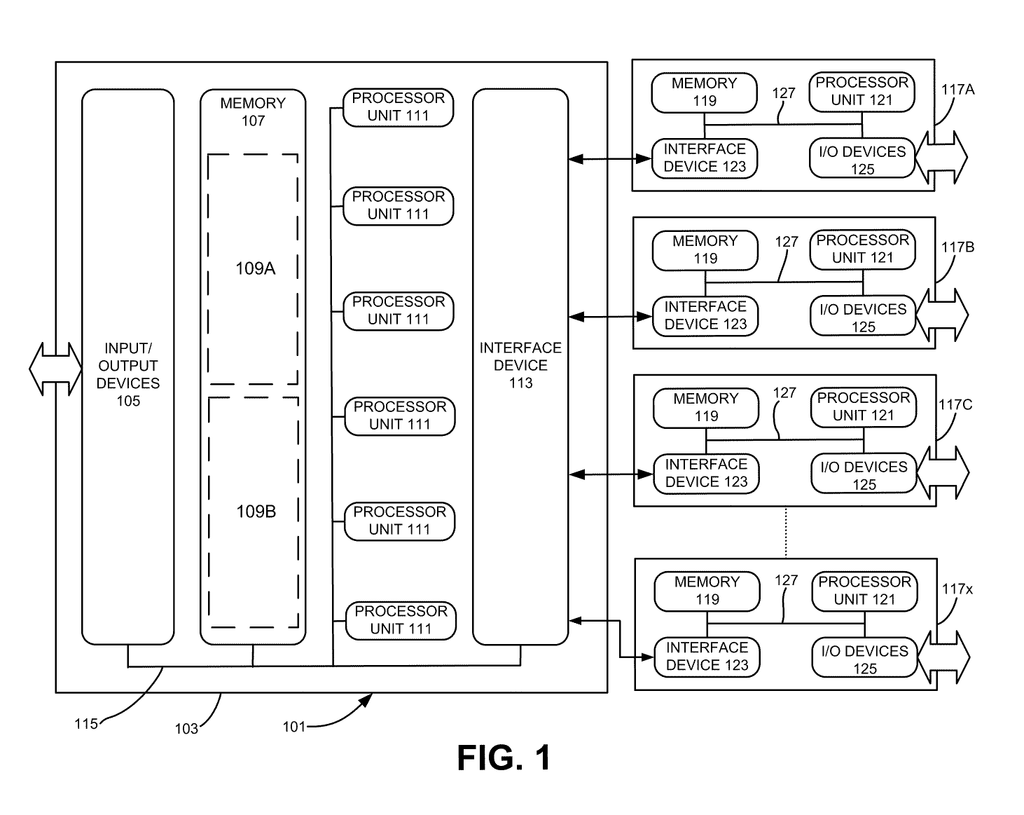

The execution of various electronic design automation processes according to embodiments of the invention may be implemented using computer-executable software instructions executed by one or more programmable computing devices. Because these embodiments of the invention may be implemented using software instructions, the components and operation of a generic programmable computer system on which various embodiments of the invention may be employed will first be described. Further, because of the complexity of some electronic design automation processes and the large size of many circuit designs, various electronic design automation tools are configured to operate on a computing system capable of simultaneously running multiple processing threads. The components and operation of a computer network having a host or master computer and one or more remote or servant computers therefore will be described with reference to FIG. 1. This operating environment is only one example of a suitable operating environment, however, and is not intended to suggest any limitation as to the scope of use or functionality of the invention.

In FIG. 1, the computer network 101 includes a master computer 103. In the illustrated example, the master computer 103 is a multi-processor computer that includes a plurality of input and output devices 105 and a memory 107. The input and output devices 105 may include any device for receiving input data from or providing output data to a user. The input devices may include, for example, a keyboard, microphone, scanner or pointing device for receiving input from a user. The output devices may then include a display monitor, speaker, printer or tactile feedback device. These devices and their connections are well known in the art, and thus will not be discussed at length here.

The memory 107 may similarly be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information.

As will be discussed in detail below, the master computer 103 runs a software application for performing one or more operations according to various examples of the invention. Accordingly, the memory 107 stores software instructions 109A that, when executed, will implement a software application for performing one or more operations. The memory 107 also stores data 109B to be used with the software application. In the illustrated embodiment, the data 109B contains process data that the software application uses to perform the operations, at least some of which may be parallel.

The master computer 103 also includes a plurality of processor units 111 and an interface device 113. The processor units 111 may be any type of processor device that can be programmed to execute the software instructions 109A, but will conventionally be a microprocessor device. For example, one or more of the processor units 111 may be a commercially generic programmable microprocessor, such as Intel® Pentium® or Xeon™ microprocessors, Advanced Micro Devices Athlon™ microprocessors or Motorola 68K/Coldfire® microprocessors. Alternately or additionally, one or more of the processor units 111 may be a custom-manufactured processor, such as a microprocessor designed to optimally perform specific types of mathematical operations. The interface device 113, the processor units 111, the memory 107 and the input/output devices 105 are connected together by a bus 115.

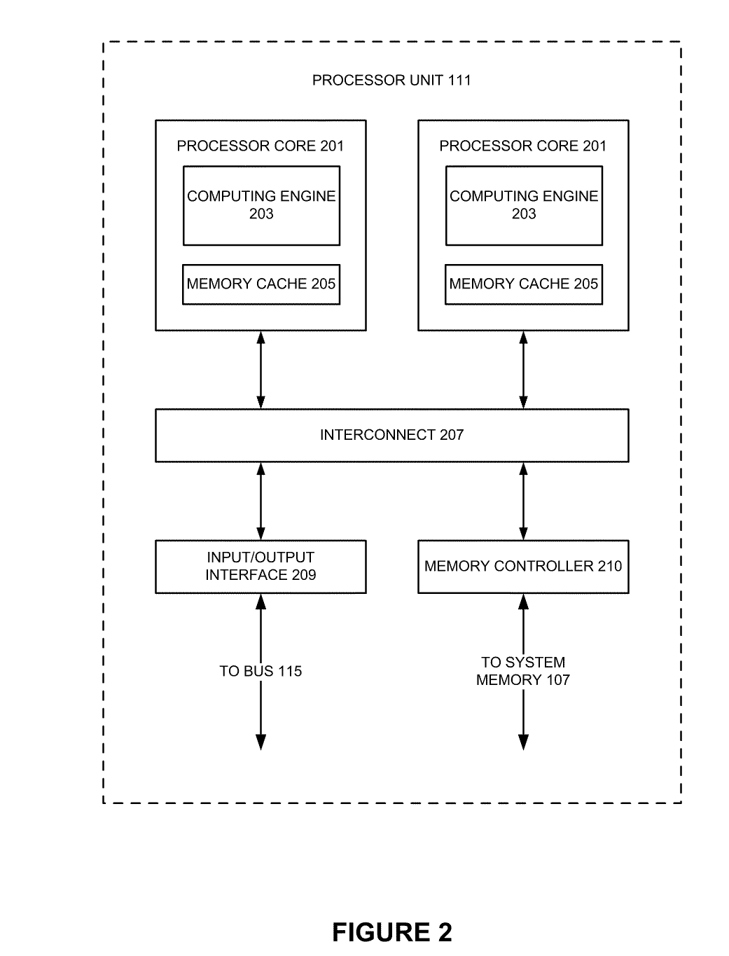

With some implementations of the invention, the master computing device 103 may employ one or more processing units 111 having more than one processor core. Accordingly, FIG. 2 illustrates an example of a multi-core processor unit 111 that may be employed with various embodiments of the invention. As seen in this figure, the processor unit 111 includes a plurality of processor cores 201. Each processor core 201 includes a computing engine 203 and a memory cache 205. As known to those of ordinary skill in the art, a computing engine contains logic devices for performing various computing functions, such as fetching software instructions and then performing the actions specified in the fetched instructions. These actions may include, for example, adding, subtracting, multiplying, and comparing numbers, performing logical operations such as AND, OR, NOR and XOR, and retrieving data. Each computing engine 203 may then use its corresponding memory cache 205 to quickly store and retrieve data and/or instructions for execution.

Each processor core 201 is connected to an interconnect 207. The particular construction of the interconnect 207 may vary depending upon the architecture of the processor unit 201. With some processor cores 201, such as the Cell microprocessor created by Sony Corporation, Toshiba Corporation and IBM Corporation, the interconnect 207 may be implemented as an interconnect bus. With other processor units 201, however, such as the Opteron™ and Athlon™ dual-core processors available from Advanced Micro Devices of Sunnyvale, Calif., the interconnect 207 may be implemented as a system request interface device. In any case, the processor cores 201 communicate through the interconnect 207 with an input/output interface 209 and a memory controller 211. The input/output interface 209 provides a communication interface between the processor unit 201 and the bus 115. Similarly, the memory controller 211 controls the exchange of information between the processor unit 201 and the system memory 107. With some implementations of the invention, the processor units 201 may include additional components, such as a high-level cache memory accessible shared by the processor cores 201.

While FIG. 2 shows one illustration of a processor unit 201 that may be employed by some embodiments of the invention, it should be appreciated that this illustration is representative only, and is not intended to be limiting. For example, some embodiments of the invention may employ a master computer 103 with one or more Cell processors. The Cell processor employs multiple input/output interfaces 209 and multiple memory controllers 211. Also, the Cell processor has nine different processor cores 201 of different types. More particularly, it has six or more synergistic processor elements (SPEs) and a power processor element (PPE). Each synergistic processor element has a vector-type computing engine 203 with 428×428 bit registers, four single-precision floating point computational units, four integer computational units, and a 556 KB local store memory that stores both instructions and data. The power processor element then controls that tasks performed by the synergistic processor elements. Because of its configuration, the Cell processor can perform some mathematical operations, such as the calculation of fast Fourier transforms (FFTs), at substantially higher speeds than many conventional processors.

It also should be appreciated that, with some implementations, a multi-core processor unit 111 can be used in lieu of multiple, separate processor units 111. For example, rather than employing six separate processor units 111, an alternate implementation of the invention may employ a single processor unit 111 having six cores, two multi-core processor units each having three cores, a multi-core processor unit 111 with four cores together with two separate single-core processor units 111, etc.

Returning now to FIG. 1, the interface device 113 allows the master computer 103 to communicate with the servant computers 117A, 117B, 117C . . . 117x through a communication interface. The communication interface may be any suitable type of interface including, for example, a conventional wired network connection or an optically transmissive wired network connection. The communication interface may also be a wireless connection, such as a wireless optical connection, a radio frequency connection, an infrared connection, or even an acoustic connection. The interface device 113 translates data and control signals from the master computer 103 and each of the servant computers 117 into network messages according to one or more communication protocols, such as the transmission control protocol (TCP), the user datagram protocol (UDP), and the Internet protocol (IP). These and other conventional communication protocols are well known in the art, and thus will not be discussed here in more detail.

Each servant computer 117 may include a memory 119, a processor unit 121, an interface device 123, and, optionally, one more input/output devices 125 connected together by a system bus 127. As with the master computer 103, the optional input/output devices 125 for the servant computers 117 may include any conventional input or output devices, such as keyboards, pointing devices, microphones, display monitors, speakers, and printers. Similarly, the processor units 121 may be any type of conventional or custom-manufactured programmable processor device. For example, one or more of the processor units 121 may be commercially generic programmable microprocessors, such as Intel® Pentium® or Xeon™ microprocessors, Advanced Micro Devices Athlon™ microprocessors or Motorola 68K/Coldfire® microprocessors. Alternately, one or more of the processor units 121 may be custom-manufactured processors, such as microprocessors designed to optimally perform specific types of mathematical operations. Still further, one or more of the processor units 121 may have more than one core, as described with reference to FIG. 2 above. For example, with some implementations of the invention, one or more of the processor units 121 may be a Cell processor. The memory 119 then may be implemented using any combination of the computer readable media discussed above. Like the interface device 113, the interface devices 123 allow the servant computers 117 to communicate with the master computer 103 over the communication interface.

In the illustrated example, the master computer 103 is a multi-processor unit computer with multiple processor units 111, while each servant computer 117 has a single processor unit 121. It should be noted, however, that alternate implementations of the invention may employ a master computer having single processor unit 111. Further, one or more of the servant computers 117 may have multiple processor units 121, depending upon their intended use, as previously discussed. Also, while only a single interface device 113 or 123 is illustrated for both the master computer 103 and the servant computers, it should be noted that, with alternate embodiments of the invention, either the computer 103, one or more of the servant computers 117, or some combination of both may use two or more different interface devices 113 or 123 for communicating over multiple communication interfaces.

With various examples of the invention, the master computer 103 may be connected to one or more external data storage devices. These external data storage devices may be implemented using any combination of computer readable media that can be accessed by the master computer 103. The computer readable media may include, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable media may also include magnetic cassettes, magnetic tapes, magnetic disks or other magnetic storage devices, punched media, holographic storage devices, or any other medium that can be used to store desired information. According to some implementations of the invention, one or more of the servant computers 117 may alternately or additionally be connected to one or more external data storage devices. Typically, these external data storage devices will include data storage devices that also are connected to the master computer 103, but they also may be different from any data storage devices accessible by the master computer 103.

It also should be appreciated that the description of the computer network illustrated in FIG. 1 and FIG. 2 is provided as an example only, and it not intended to suggest any limitation as to the scope of use or functionality of alternate embodiments of the invention.

### Electronic Design Automation

As previously noted, various embodiments of the invention are related to electronic design automation. In particular, various implementations of the invention may be used to improve the operation of electronic design automation software tools that identify, verify and/or modify design data for manufacturing a microdevice, such as a microcircuit. As used herein, the terms “design” and “design data” are intended to encompass data describing an entire microdevice, such as an integrated circuit device or micro-electromechanical system (MEMS) device. This term also is intended to encompass a smaller set of data describing one or more components of an entire microdevice, however, such as a layer of an integrated circuit device, or even a portion of a layer of an integrated circuit device. Still further, the terms “design” and “design data” also are intended to encompass data describing more than one microdevice, such as data to be used to create a mask or reticle for simultaneously forming multiple microdevices on a single wafer. It should be noted that, unless otherwise specified, the term “design” as used herein is intended to encompass any type of design, including both a physical layout design and a logical design.

Designing and fabricating microcircuit devices involve many steps during a ‘design flow’ process. These steps are highly dependent on the type of microcircuit, its complexity, the design team, and the fabricator or foundry that will manufacture the microcircuit from the design. Several steps are common to most design flows, however. First, a design specification is modeled logically, typically in a hardware design language (HDL). Once a logical design has been created, various logical analysis processes are performed on the design to verify its correctness. More particularly, software and hardware “tools” verify that the logical design will provide the desired functionality at various stages of the design flow by running software simulators and/or hardware emulators, and errors are corrected. For example, a designer may employ one or more functional logic verification processes to verify that, given a specified input, the devices in a logical design will perform in the desired manner and provide the appropriate output.

In addition to verifying that the devices in a logic design will provide the desired functionality, some designers may employ a design logic verification process to verify that the logical design meets specified design requirements. For example, a designer may create rules such as, e.g., every transistor gate in the design must have an electrical path to ground that passes through no more than three other devices, or every transistor that connects to a specified power supply also must be connected to a corresponding ground node, and not to any other ground node. A design logic verification process then will determine if a logical design complies with specified rules, and identify occurrences where it does not.

After the logical design is deemed satisfactory, it is converted into physical design data by synthesis software. This physical design data or “layout” design data may represent, for example, the geometric elements that will be written onto a mask used to fabricate the desired microcircuit device in a photolithographic process at a foundry. For conventional mask or reticle writing tools, the geometric elements typically will be polygons of various shapes. Thus, the layout design data usually includes polygon data describing the features of polygons in the design. It is very important that the physical design information accurately embody the design specification and logical design for proper operation of the device. Accordingly, after it has been created during a synthesis process, the physical design data is compared with the original logical design schematic in a process sometimes referred to as a “layout-versus-schematic” (LVS) process.

Once the correctness of the logical design has been verified, and geometric data corresponding to the logical design has been created in a layout design, the geometric data then may be analyzed. For example, because the physical design data is employed to create masks used at a foundry, the data must conform to the foundry's requirements. Each foundry specifies its own physical design parameters for compliance with their processes, equipment, and techniques. Accordingly, the design flow may include a process to confirm that the design data complies with the specified parameters. During this process, the physical layout of the circuit design is compared with design rules in a process commonly referred to as a “design rule check” (DRC) process. In addition to rules specified by the foundry, the design rule check process may also check the physical layout of the circuit design against other design rules, such as those obtained from test chips, general knowledge in the industry, previous manufacturing experience, etc.

With modern electronic design automation design flows, a designer may additionally employ one or more “design-for-manufacture” (DFM) software tools. As previously noted, design rule check processes attempt to identify, e.g., elements representing structures that will almost certainly be improperly formed during a manufacturing process. “Design-For-Manufacture” tools, however, provide processes that attempt to identify elements in a design representing structures with a significant likelihood of being improperly formed during the manufacturing process. A “design-for-manufacture” process may additionally determine what impact the improper formation of the identified elements will have on the yield of devices manufactured from the circuit design, and/or modifications that will reduce the likelihood that the identified elements will be improperly formed during the manufacturing process. For example, a “design-for-manufacture” (DFM) software tool may identify wires that are connected by only a single via, determine the yield impact for manufacturing a circuit from the design based upon the probability that each individual single via will be improperly formed during the manufacturing process, and then identify areas where redundant vias can be formed to supplement the single vias.

It should be noted that, in addition to “design-for-manufacture,” various alternate terms are used in the electronic design automation industry. Accordingly, as used herein, the term “design-for-manufacture” or “design-for-manufacturing” is intended to encompass any electronic design automation process that identifies elements in a design representing structures that may be improperly formed during the manufacturing process. Thus, “design-for-manufacture” (DFM) software tools will include, for example, “lithographic friendly design” (LFD) tools that assist designers to make trade-off decisions on how to create a circuit design that is more robust and less sensitive to lithographic process windows. They will also include “design-for-yield” (DFY) electronic design automation tools, “yield assistance” electronic design automation tools, and “chip cleaning” and “design cleaning” electronic design automation tools.

After a designer has used one or more geometry analysis processes to verify that the physical layout of the circuit design is satisfactory, the designer may then perform one or more simulation processes to simulate the operation of a manufacturing process, in order to determine how the design will actually be realized by that particular manufacturing process. A simulation analysis process may additionally modify the design to address any problems identified by the simulation. For example, some design flows may employ one or more processes to simulate the image formed by the physical layout of the circuit design during a photolithographic process, and then modify the layout design to improve the resolution of the image that it will produce during a photolithography process.

These resolution enhancement techniques (RET) may include, for example, modifying the physical layout using optical proximity correction (OPC) or by the addition of sub-resolution assist features (SRAF). Other simulation analysis processes may include, for example, phase shift mask (PSM) simulation analysis processes, etch simulation analysis processes and planarization simulation analysis processes. Etch simulation analysis processes simulate the removal of materials during a chemical etching process, while planarization simulation processes simulate the polishing of the circuit's surface during a chemical-mechanical etching process. These simulation analysis processes may identify, for example, regions where an etch or polishing process will not leave a sufficiently planar surface. These simulation analysis processes may then modify the physical layout design to, e.g., include more geometric elements in those regions to increase their density.

Once a physical layout design has been finalized, the geometric elements in the design are formatted for use by a mask or reticle writing tool. Masks and reticles typically are made using tools that expose a blank reticle or mask substrate to an electron or laser beam (or to an array of electron beams or laser beams), but most mask writing tools are able to only “write” certain kinds of polygons, however, such as right triangles, rectangles or other trapezoids. Moreover, the sizes of the polygons are limited physically by the maximum beam (or beam array) size available to the tool. Accordingly, the larger geometric elements in a physical layout design data will typically be “fractured” into the smaller, more basic polygons that can be written by the mask or reticle writing tool.

It should be appreciated that various design flows may repeat one or more processes in any desired order. Thus, with some design flows, geometric analysis processes can be interleaved with simulation analysis processes and/or logical analysis processes. For example, once the physical layout of the circuit design has been modified using resolution enhancement techniques, then a design rule check process or design-for-manufacturing process may be performed on the modified layout, Further, these processes may be alternately repeated until a desired degree of resolution for the design is obtained. Similarly, a design rule check process and/or a design-for-manufacturing process may be employed after an optical proximity correction process, a phase shift mask simulation analysis process, an etch simulation analysis process or a planarization simulation analysis process. Examples of electronic design tools that employ one or more of the logical analysis processes, geometry analysis processes or simulation analysis processes discussed above are described in U.S. Pat. No. 6,230,299 to McSherry et al., issued May 8, 2001, U.S. Pat. No. 6,249,903 to McSherry et al., issued Jun. 19, 2001, U.S. Pat. No. 6,339,836 to Eisenhofer et al., issued Jan. 15, 2002, U.S. Pat. No. 6,397,372 to Bozkus et al., issued May 28, 2002, U.S. Pat. No. 6,415,421 to Anderson et al., issued Jul. 2, 2002, and U.S. Pat. No. 6,425,113 to Anderson et al., issued Jul. 23, 2002, each of which are incorporated entirely herein by reference.

### Software Tools for Simulation, Verification or Modification of a Circuit Layout

To facilitate an understanding of various embodiments of the invention, one such software tool for automatic design automation, directed to the analysis and modification of a design for an integrated circuit, will now be generally described. As previously noted, the terms “design” and “design data” are used herein to encompass data describing an entire microdevice, such as an integrated circuit device or micro-electromechanical system (MEMS) device. These terms also are intended, however, to encompass a smaller set of data describing one or more components of an entire microdevice, such as a layer of an integrated circuit device, or even a portion of a layer of an integrated circuit device. Still further, the terms “design” and “design data” also are intended to encompass data describing more than one microdevice, such as data to be used to create a mask or reticle for simultaneously forming multiple microdevices on a single wafer. As also previously noted, unless otherwise specified, the term “design” as used herein is intended to encompass any type of design, including both physical layout designs and logical designs.

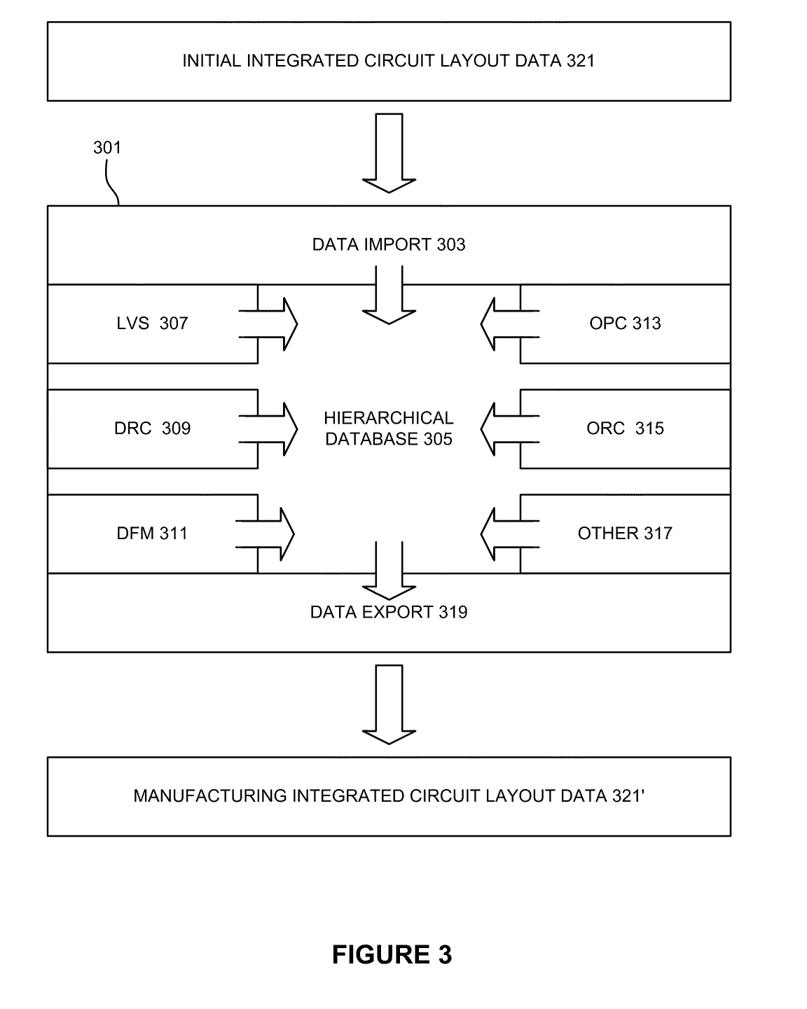

As seen in FIG. 3, a layout design analysis tool system 301, which may be implemented by a variety of different software applications, includes a data import module 303 and a hierarchical database 305. The analysis tool 301 also includes a layout-versus-schematic (LVS) verification module 307, a design rule check (DRC) module 309, a design-for-manufacturing (DFM) module 311, an optical proximity correction (OPC) module 313, and an optical proximity rule check (ORC) module 315. The analysis tool 301 may further include other modules 317 for performing additional functions as desired, such as a phase shift mask (PSM) module (not shown), an etch simulation analysis module (not shown) and/or a planarization simulation analysis module (not shown). The tool 301 also has a data export module 319. One example of such an analysis tool is the Calibre family of software applications available from Mentor Graphics Corporation of Wilsonville, Oreg.

Initially, the tool 301 receives data 321 describing a physical layout design for an integrated circuit. The layout design data 321 may be in any desired format, such as, for example, the Graphic Data System II (GDSII) data format or the Open Artwork System Interchange Standard (OASIS) data format proposed by Semiconductor Equipment and Materials International (SEMI). Other formats for the data 321 may include an open source format named Open Access, Milkyway by Synopsys, Inc., and EDDM by Mentor Graphics, Inc. The layout data 321 includes geometric elements for manufacturing one or more portions of an integrated circuit device. For example, the initial integrated circuit layout data 321 may include a first set of polygons for creating a photolithographic mask that in turn will be used to form an isolation region of a transistor, a second set of polygons for creating a photolithographic mask that in turn will be used to form a contact electrode for the transistor, and a third set of polygons for creating a photolithographic mask that in turn will be used to form an interconnection line to the contact electrode. The initial integrated circuit layout data 321 may be converted by the data import module 303 into a format that can be more efficiently processed by the remaining components of the tool 301.

Once the data import module 303 has converted the original integrated circuit layout data 321 to the appropriate format, the layout data 321 is stored in the hierarchical database 305 for use by the various operations executed by the modules 305-317. Next, the layout-versus-schematic module 307 checks the layout design data 321 in a layout-versus-schematic process, to verify that it matches the original design specifications for the desired integrated circuit. If discrepancies between the layout design data 321 and the logical design for the integrated circuit are identified, then the layout design data 321 may be revised to address one or more of these discrepancies. Thus, the layout-versus-schematic process performed by the layout-versus-schematic module 307 may lead to a new version of the layout design data with revisions. According to various implementations of the invention tool 301, the layout data 321 may be manually revised by a user, automatically revised by the layout-versus-schematic module 307, or some combination thereof.

Next, the design rule check module 309 confirms that the verified layout data 321 complies with defined geometric design rules. If portions of the layout data 321 do not adhere to or otherwise violate the design rules, then the layout data 321 may be modified to ensure that one or more of these portions complies with the design rules. The design rule check process performed by the design rule check module 309 thus also may lead to a new version of the layout design data with various revisions. Again, with various implementations of the invention tool 301, the layout data 321 may be manually modified by a user, automatically modified by the design rule check module 309, or some combination thereof.

The modified layout data 321 is then processed by the design for manufacturing module 311. As previously noted, a “design-for-manufacture” processes attempts to identify elements in a design representing structures with a significant likelihood of being improperly formed during the manufacturing process. A “design-for-manufacture” process may additionally determine what impact the improper formation of the identified structures will have on the yield of devices manufactured from the circuit design, and/or modifications that will reduce the likelihood that the identified structures may be improperly formed during the manufacturing process. For example, a “design-for-manufacture” (DFM) software tool may identify wires that are connected by single vias, determine the yield impact based upon the probability that each individual single via will be improperly formed during the manufacturing process, and then identify areas where redundant visa can be formed to supplement the single vias.

The processed layout data 321 is then passed to the optical proximity correction module 313, which corrects the layout data 321 for manufacturing distortions that would otherwise occur during the lithographic patterning. For example, the optical proximity correction module 313 may correct for image distortions, optical proximity effects, photoresist kinetic effects, and etch loading distortions. The layout data 321 modified by the optical proximity correction module 313 then is provided to the optical process rule check module 315

The optical process rule check module 315 (more commonly called the optical rules check module or ORC module) ensures that the changes made by the optical proximity correction module 313 are actually manufacturable, a “downstream-looking” step for layout verification. This compliments the “upstream-looking” step of the LVS performed by the LVS module 307 and the self-consistency check of the DRC process performed by the DRC module 309, adding symmetry to the verification step. Thus, each of the processes performed by the design for manufacturing process 311, the optical proximity correction module 313, and the optical process rule check module 315 may lead to a new version of the layout design data with various revisions.

As previously noted, other modules 317 may be employed to perform alternate or additional manipulations of the layout data 321, as desired. For example, some implementations of the tool 301 may employ, for example, a phase shift mask module. As previously discussed, with a phase-shift mask (PSM) analysis (another approach to resolution enhancement technology (RET)), the geometric elements in a layout design are modified so that the pattern they create on the reticle will introduce contrast-enhancing interference fringes in the image. The tool 301 also may alternately or additionally employ, for example, an etch simulation analysis processes or a planarization simulation analysis processes. The process or processes performed by each of these additional modules 317 may also lead to the creation of a new version of the layout data 321 that includes revisions.

After all of the desired operations have been performed on the initial layout data 321, the data export module 319 converts the processed layout data 321 into manufacturing integrated circuit layout data 323 that can be used to form one or more masks or reticules to manufacture the integrated circuit (that is, the data export module 319 converts the processed layout data 321 into a format that can be used in a photolithographic manufacturing process). Masks and reticles typically are made using tools that expose a blank reticle or mask substrate to an electron or laser beam (or to an array of electron beams or laser beams), but most mask writing tools are able to only “write” certain kinds of polygons, however, such as right triangles, rectangles or other trapezoids. Moreover, the sizes of the polygons are limited physically by the maximum beam (or beam array) size available to the tool.

Accordingly, the data export module 319 may “fracture” larger geometric elements in the layout design, or geometric elements that are not right triangles, rectangles or trapezoids (which typically are a majority of the geometric elements in a layout design) into the smaller, more basic polygons that can be written by the mask or reticle writing tool. Of course, the data export module 319 may alternately or additionally convert the processed layout data 321 into any desired type of data, such as data for use in a synthesis process (e.g., for creating an entry for a circuit library), data for use in a place-and-route process, data for use in calculating parasitic effects, etc. Further, the tool 301 may store one or more versions of the layout 321 containing different modifications, so that a designer can undo undesirable modifications. For example, the hierarchical database 305 may store alternate versions of the layout data 321 created during any step of the process flow between the modules 307-317.

### Data Organization

The design of a new integrated circuit may include the interconnection of millions of transistors, resistors, capacitors, or other electrical structures into logic circuits, memory circuits, programmable field arrays, and other circuit devices. In order to allow a computer to more easily create and analyze these large data structures (and to allow human users to better understand these data structures), they are often hierarchically organized into smaller data structures, typically referred to as “cells.” Thus, for a microprocessor or flash memory design, all of the transistors making up a memory circuit for storing a single bit may be categorized into a single “bit memory” cell. Rather than having to enumerate each transistor individually, the group of transistors making up a single-bit memory circuit can thus collectively be referred to and manipulated as a single unit. Similarly, the design data describing a larger 16-bit memory register circuit can be categorized into a single cell. This higher level “register cell” might then include sixteen bit memory cells, together with the design data describing other miscellaneous circuitry, such as an input/output circuit for transferring data into and out of each of the bit memory cells. Similarly, the design data describing a 128 kB memory array can then be concisely described as a combination of only 64,000 register cells, together with the design data describing its own miscellaneous circuitry, such as an input/output circuit for transferring data into and out of each of the register cells.

By categorizing microcircuit design data into hierarchical cells, large data structures can be processed more quickly and efficiently. For example, a circuit designer typically will analyze a design to ensure that each circuit feature described in the design complies with specified design rules. With the above example, instead of having to analyze each feature in the entire 128 kB memory array, a design rule check process can analyze the features in a single bit cell. If the cells are identical, then the results of the check will then be applicable to all of the single bit cells. Once it has confirmed that one instance of the single bit cells complies with the design rules, the design rule check process then can complete the analysis of a register cell simply by analyzing the features of its additional miscellaneous circuitry (which may itself be made of up one or more hierarchical cells). The results of this check will then be applicable to all of the register cells. Once it has confirmed that one instance of the register cells complies with the design rules, the design rule check software application can complete the analysis of the entire 128 kB memory array simply by analyzing the features of the additional miscellaneous circuitry in the memory array. Thus, the analysis of a large data structure can be compressed into the analyses of a relatively small number of cells making up the data structure.

With various examples of the invention, layout design data may include two different types of data: “drawn layer” design data and “derived layer” design data. The drawn layer data describes geometric elements that will be used to form structures in layers of material to produce the integrated circuit. The drawn layer data will usually include polygons that will be used to form structures in metal layers, diffusion layers, and polysilicon layers. The derived layers will then include features made up of combinations of drawn layer data and other derived layer data. Thus, with a transistor gate, derived layer design data describing the gate may be derived from the intersection of a polygon in the polysilicon material layer and a polygon in the diffusion material layer.

For example, a design rule check process performed by the design rule check module 309 typically will perform two types of operations: “check” operations that confirm whether design data values comply with specified parameters, and “derivation” operations that create derived layer data. A transistor gate design data thus may be created by the following derivation operation:

gate=diff AND poly

The results of this operation will be a “layer” of data identifying all intersections of diffusion layer polygons with polysilicon layer polygons. Likewise, a p-type transistor gate, formed by doping the diffusion layer with n-type material, is identified by the following derivation operation:

pgate=nwell AND gate

The results of this operation then will be another “layer” of data identifying all transistor gates (i.e., intersections of diffusion layer polygons with polysilicon layer polygons) where the polygons in the diffusion layer have been doped with n-type material.

A check operation performed by the design rule check module 309 will then define a parameter or a parameter range for a data design value. For example, a user may want to ensure that no metal wiring line is within a micron of another wiring line. This type of analysis may be performed by the following check operation:

external metal<1

The results of this operation will identify each polygon in the metal layer design data that are closer than one micron to another polygon in the metal layer design data.

Also, while the above operation employs drawn layer data, check operations may be performed on derived layer data as well. For example, if a user wanted to confirm that no transistor gate is located within one micron of another gate, the design rule check process might include the following check operation:

external gate<1

The results of this operation will identify all gate design data representing gates that are positioned less than one micron from another gate. It should be appreciated, however, that this check operation cannot be performed until a derivation operation identifying the gates from the drawn layer design data has been performed.

The design of a new integrated circuit may include the interconnection of millions of transistors, resistors, capacitors, or other electrical structures into logic circuits, memory circuits, programmable field arrays, and other circuit devices. In order to allow a computer to more easily create and analyze these large data structures (and to allow human users to better understand these data structures), they are often hierarchically organized into smaller data structures, typically referred to as “cells.” Thus, for a microprocessor or flash memory design, all of the transistors making up a memory circuit for storing a single bit may be categorized into a single “bit memory” cell. Rather than having to enumerate each transistor individually, the group of transistors making up a single-bit memory circuit can thus collectively be referred to and manipulated as a single unit. Similarly, the design data describing a larger 16-bit memory register circuit can be categorized into a single cell. This higher level “register cell” might then include sixteen bit memory cells, together with the design data describing other miscellaneous circuitry, such as an input/output circuit for transferring data into and out of each of the bit memory cells. Similarly, the design data describing a 128 kB memory array can then be concisely described as a combination of only 64,000 register cells, together with the design data describing its own miscellaneous circuitry, such as an input/output circuit for transferring data into and out of each of the register cells.

By categorizing microcircuit design data into hierarchical cells, large data structures can be processed more quickly and efficiently. For example, a circuit designer typically will analyze a design to ensure that each circuit feature described in the design complies with design rules specified by the foundry that will manufacture microcircuits from the design. With the above example, instead of having to analyze each feature in the entire 128 kB memory array, a design rule check process can analyze the features in a single bit cell. The results of the check will then be applicable to all of the single bit cells. Once it has confirmed that one instance of the single bit cells complies with the design rules, the design rule check process then can complete the analysis of a register cell simply by analyzing the features of its additional miscellaneous circuitry (which may itself be made of up one or more hierarchical cells). The results of this check will then be applicable to all of the register cells. Once it has confirmed that one instance of the register cells complies with the design rules, the design rule check software application can complete the analysis of the entire 128 kB memory array simply by analyzing the features of the additional miscellaneous circuitry in the memory array. Thus, the analysis of a large data structure can be compressed into the analyses of a relatively small number of cells making up the data structure.

### Layout-Versus-Schematic Process

As previously noted, some electronic design automation flows will include a layout-versus-schematic process, such as the CALIBRE LVS tool available from Mentor Graphics Corporation of Wilsonville, Oreg. A layout-versus-schematic process will analyze a layout design to create a circuit schematic corresponding to the layout design. Typically, a layout-versus-schematic process will perform a device or “instance” recognition operation. With this operation, the layout-versus-schematic process will recognize when combinations of geometric elements in the layout design are arranged to form a specific device or device “instance,” such as a resistor, transistor, diode or the like. For example, a recognition operation may select a geometric element in a design, and then identify its relationship to adjacent and overlapping geometric elements in the various layers of the design. This analysis is repeated for each relevant adjacent and overlapping geometric element, until the device recognition operation determines that a combination of the geometric elements matches a predefined arrangement corresponding to a specified device. The device recognition operation then recognizes that the combination of the geometric elements represents the specified device.

Some layout-versus-schematic processes may also perform a gate recognition operation to recognize the representation of logic gates from transistor-level data in a circuit design. For example, this operation may recognize an inverter from a particular arrangement of transistors that themselves were previously recognized from geometric elements. Similarly, some layout-versus-schematic processes may provide a logic injection operation that substitute devices (or combination of devices) in a design with other logic. Logic injection may be used, for example, in hierarchical circuit comparison to reduce memory consumption by replacing common logic circuits with new, primitive elements. Still further, some layout-versus-schematic processes may perform a device reduction operation. With this operation, a layout-versus-schematic process will reduce a plurality of previously-identified devices into a single, corresponding device. For example, this operation may be used to reduce a plurality of parallel resistor representations in a circuit design into a single, equivalent resistor representation.

Once a layout-versus-schematic process has recognized devices from the geometric elements in a layout design, it will analyze the connectivity of these devices to generate a schematic representation (e.g., a netlist) of the circuit described in the layout design data. It will then compare this extracted schematic design with the original schematic design, to confirm that the extracted schematic design matches the original schematic design. If the extracted schematic design differs from the original schematic design, the layout-versus-schematic processes will recognize that there are discrepancies in the layout design data from which the extracted schematic design was generated, and identify those discrepancies to a designer.

As part of the analysis process, a layout-versus-schematic process may identify low-level discrepancies in the layout design data, such as shorts. As will be appreciated by those of ordinary skill in the art, even a single misplaced geometric element in a layout design may cause two nets to be electrically connected in the manufactured circuit. Accordingly, a designer will attempt to identify and correct any shorts in layout design data prior to manufacturing a lithographic mask from that data.

In addition to low-level discrepancies, a layout-versus-schematic process will also identify high-level discrepancies, such as, for example, the misconnection of devices or nets. Some layout-versus-schematic processes may, for example, create mathematical graphs corresponding to both the original schematic design and the extracted schematic design. The graphs may, for example, represent each device and net in the schematic with a node in the graph. Using graph comparison techniques, these layout-versus-schematic processes can then determine the similarities and differences between the extracted schematic design and the extracted schematic design. For example, the original schematic design may include a unique arrangement of transistors (relative to other devices) labeled T1, T2 and T3. In the layout design data, and thus the extracted schematic design, however, the transistors may be labeled Ti, Tj, and Tk. By identifying the unique arrangement of these transistors in both schematic designs, the layout-versus-schematic process can determine that transistor Ti corresponds to transistor Ti, transistor T2 corresponds to transistor Tj, and transistor T3 corresponds to transistor Tk. After corresponding devices and nets have been identified, a layout-versus-schematic process can identify misconnections in the extracted schematic design. For example, by comparing characteristics of the graphs corresponding to the schematic designs, a layout-versus-schematic process may determine that the extracted schematic design has a transistor Tx connected to a net A. The layout-versus-schematic process may also determine that the extracted schematic design has a corresponding transistor (e.g., transistor T11) that is instead connected to a net corresponding to another net in the original schematic design (e.g., a net B). From this information, the layout-versus-schematic process can suggest to a designer that the layout design data be modified to ensure that the transistor T11 is disconnected from the net corresponding to net B in the original schematic design, and be connected to the net corresponding to net A in the original schematic design.

### Shorts

As previously noted, some layout-versus-schematic processes may detect low-level discrepancies in layout design data, such as shorts. As used herein, the terms “short” and “shorts” refer to the representation of a short in a schematic or layout design of an integrated circuit portion, rather than to the physical short produced when an integrated circuit is manufactured from the design.

For example, some layout-versus-schematic processes (or other electronic design automation processes with corresponding functionality) may perform a connectivity extraction operation to create a connectivity model showing what geometric elements are electrically connected, based upon the arrangement of the geometric elements and connection rules that define, e.g., which layers should be treated as electrically connected by vias. For example, a connection rule may specify that a via overlapping a metal 1 polygon, a metal2 polygon and a metal 3 polygon will electrically connect the metal1 and metal2 polygons, but not the metal3 polygon.

Once a connectivity model has been created, some layout-versus-schematic processes (or corresponding electronic design automation processes) will then perform a short isolation operation. This operation will analyze the geometric elements in the connectivity model, to detect when one net (e.g., net A) is at one end of a connectivity path, and another, different net (e.g., B) is at another end of the connectivity path. With various examples of layout-versus-schematic processes, net labels or other identifiers may be manually assigned by a user, automatically generated, or both, for use by the layout-versus-schematic process. In some cases, if geometric elements are not prelabeled with net names, a layout-versus-schematic process may still detect a short after it has compared the extracted schematic design to the original schematic design to identify corresponding devices and nets, as described in more detail above.

Once the short isolation operation has detected one or more shorts, a designer will then attempt to modify the layout design data to remove or otherwise correct the shorts. With conventional electronic design automation tools, a short isolation operation is run in a “batch” format. That is, the short isolation operation detects all of the shorts in the layout design data at one time. To optimize design time, a designer must therefore attempt to fix or otherwise correct every identified short before performing a subsequent short isolation operation. Since many shorts are complicated and cannot be corrected on an initial pass, this arrangement makes short correction very difficult.

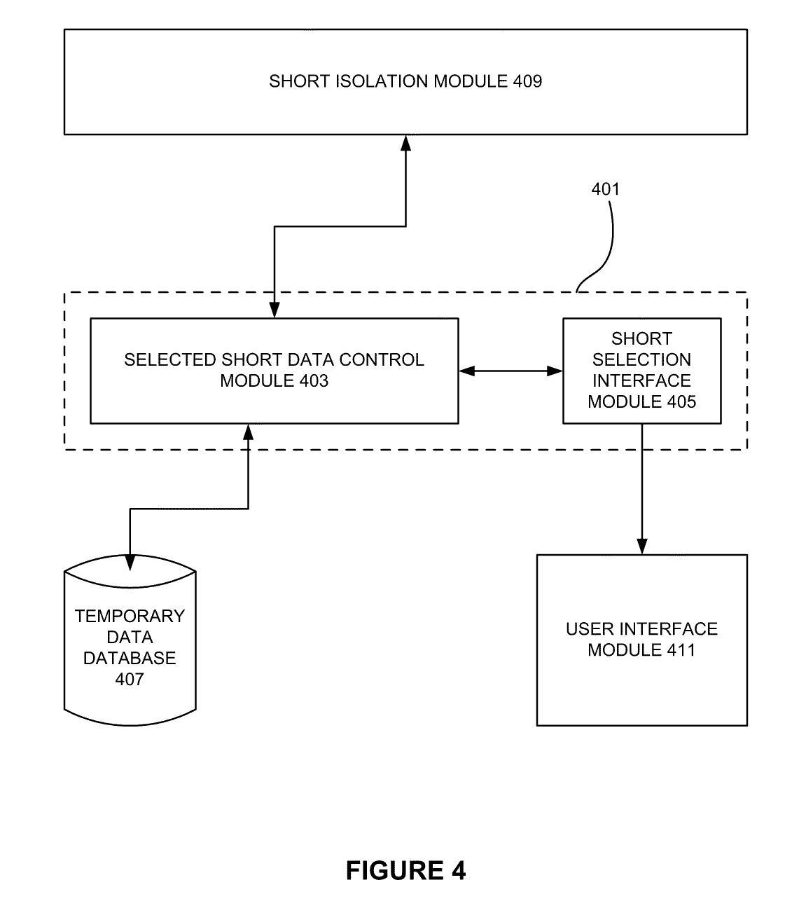

FIG. 4 illustrates an example of a user-guided short correction tool 401 that may be implemented according to various examples of the invention. As seen in this figure, the user-guided short correction tool 401 includes a selected short data control module 403 and a short selection interface module 405. As also seen in this figure, the user-guided short correction tool 401 is connected to a temporary data database 407, a short isolation module 409, and a user interface module 411 of the overall electronic design automation process (which typically may be a layout-versus-schematic process, as discussed in detail above).

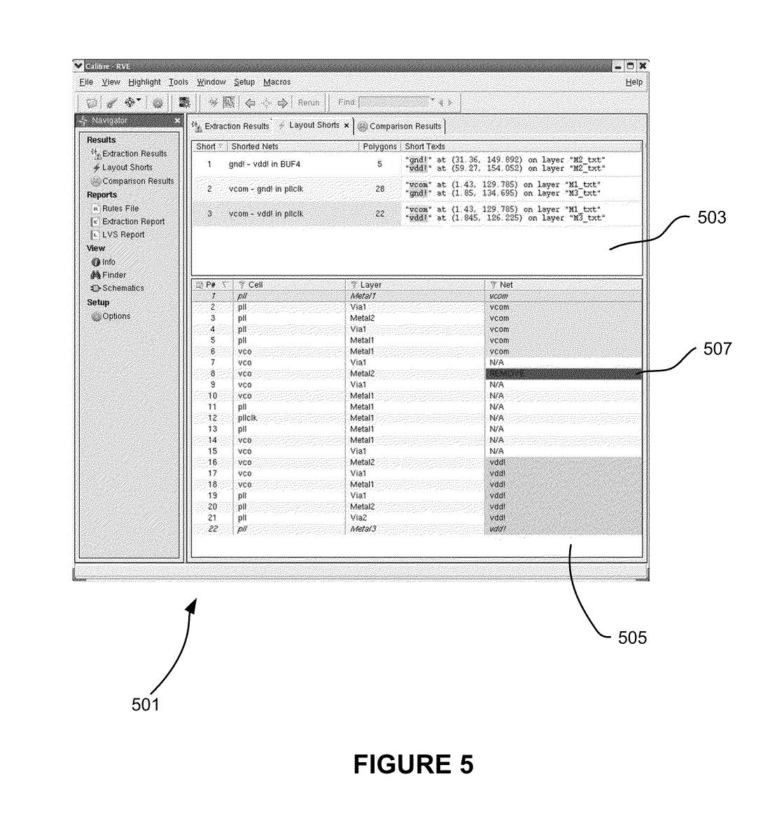

Initially, the short isolation module 409 performs a short isolation operation on a set of layout design data, and provides a set of identified shorts to the selected short data control module 403 of the user-guided short correction tool 401. Next, the short selection interface module 405 creates a user interface listing the identified shorts, and provides this interface to the user interface module 411 of the overall electronic design automation process. In response, the user interface module 411 displays a user interface that lists the shorts, such as the user interface 501 illustrated in FIG. 5. As seen in this figure, the user interface 501 includes a display region 503 listing the identified shorts. The display region 503 may include, for each short, for example, a first column with a numerical identifier for the short, a second column listing the nets that are erroneously connected by the short, the number of geometric elements (e.g., polygons) included in the path of the short, and a fourth column providing the relative positions of the connected nets in the design data.

With various embodiments of the invention, a user can select one or more specific shorts for analysis in a subsequent short isolation process. With some implementations of the invention, selecting a specific short from the list of identified shorts will cause the short selection interface module 405 to display more information regarding the selected short to the user. For example, as shown in FIG. 5, the user interface 501 may provide a display region 505 for illustrating additional information relating to the selected short. In the illustrated example, the display region 505 lists information for each geometric element in the path of the selected short (with this example, the third short in the list shown in the display region 503). More particularly, for each polygon the in path of the selected short, the display region 507 includes a column providing a number for the geometric element, the hierarchical cell in which the geometric element is located, the design layer in which the geometric element is located, and the net with which the geometric element is associated.

With some implementations of the invention, the user interface 501 may additionally provide a designer with correction data to fix or otherwise correct the short. For example, in the illustrated user interface, the fourth column of the display region 505 provides a drop-down menu control for each geometric element. Using this control, a designer can associate the geometric element with another net, or instruct that it be removed from the design entirely with the “Remove” command 507. Of course, still other implementations of the invention may provide alternate techniques for fixing or otherwise correcting selected shorts. Some implementations of the invention may alternately or additionally allow the user-guided short correction tool 401 to interface with a conventional layout data manipulation tool. With these implementations of the invention, a user may fix or otherwise correct a selected short by, for example, placing a “blocking” rectangle over a geometric element in the short path, thereby removing the covered portion of the geometric element from the layout design.

After the designer has selected a subset of the identified shorts for correction and provided correction data to correct those shorts, the short selection interface module 405 provides the short selection data and the correction data to the selected short data control module 403. It should be appreciated, however, that, with alternate implementations of the invention, the user interface module 411 may provide the short selection data, the correction data, or some combination of both directly to the selected short data control module 403. In response to receiving the short selection data and the correction data, the selected short data control module 403 relays the provided data to the short isolation module 409. The short isolation module 409 will then perform another short isolation operation for only the selected subset of shorts from the previous set of identified shorts, using the correction data provided by the designer. This process can be repeated until all of the selected shorts have been corrected. Further, a designer can select even fewer shorts to be analyzed during each iteration, if desired.

With various examples of the invention, the selected short data control module 403 will store temporary data in the temporary data database 407. For example, with some implementations of the invention, the selected short data control module 403 may store the layout design data (including the connectivity model) employed to identify shorts during the initial short isolation operation. With this arrangement, a connectivity extraction operation need not be repeated for subsequent iterations of the short isolation module, or performed on only a limited basis. Further, if a designer determines that a short is too difficult or time consuming to correct immediately, the designer can revert back to earlier short identification results for correction. Still further, with this arrangement, the designer need not implement successful short corrections immediately. Instead, the designer can store successful short correction data for application to the original layout design data at a later time. Thus, correction edits to the design data can be made to a copy of the layout design data and/or connectivity information (e.g., where a correction for a first short may be related to a correction for a second short), or subsequent correction edits can be made on a new copy of the layout design data and/or connectivity information (e.g., where a designer has given up on correcting a particular short for the moment).

Various examples of the invention may alternately or additionally allow a user to select the algorithm that is employed to identify shorts. For example, some short identification tools may only identify a short by a particular path, such as the path containing the smallest number of geometric elements. Various implementations of the invention, however, may allow a user to select from a variety of techniques for identifying a short. For example, some implementations of the invention may allow a user to determine that shorts be identified by the shortest path by distance, the shortest path by the number of geometric elements, the top x of shortest paths by distance (where x is a user-selected number), the top x of shortest paths by the number of geometric elements (where x is a user-selected number, etc.

By allowing a designer to .selectively determine which shorts to correct and reexamine in a subsequent short isolation process, a user can rerun a short isolation operation on a subset of shorts (including a single short or group of shorts) from among a set of initially identified shorts. In this manner, a designer can concentrate on correcting a particular short, testing supplied correction data again and again consecutively, until the short is corrected.

### Schematic Fix Visualization

As discussed in detail above, various layout-versus-schematic processes may identify high-level discrepancies in an extracted schematic design. With conventional layout-versus-schematic processes, the layout-versus-schematic process may provide a designer with text listing of the discrepancies. More sophisticated layout-versus-schematic processes may even provide a designer with text “hints” for correcting discrepancies. This type of hint may be, for example, a text message suggesting that the designer change the connection for a transistor T1 from net B to net A. Even with these text “hints,” however, it may be difficult for a designer to easily effect a correction.

Various implementations of the invention may instead provide graphical images showing the correction that should be made by a designer. More particularly, various implementations of the invention may provide a designer with a first image showing the correct connection as it appears in the original schematic design, a second image graphically showing how the connection is inaccurate in the extracted schematic design, and a third image graphically showing how the proper correction should appear in the extracted schematic design.

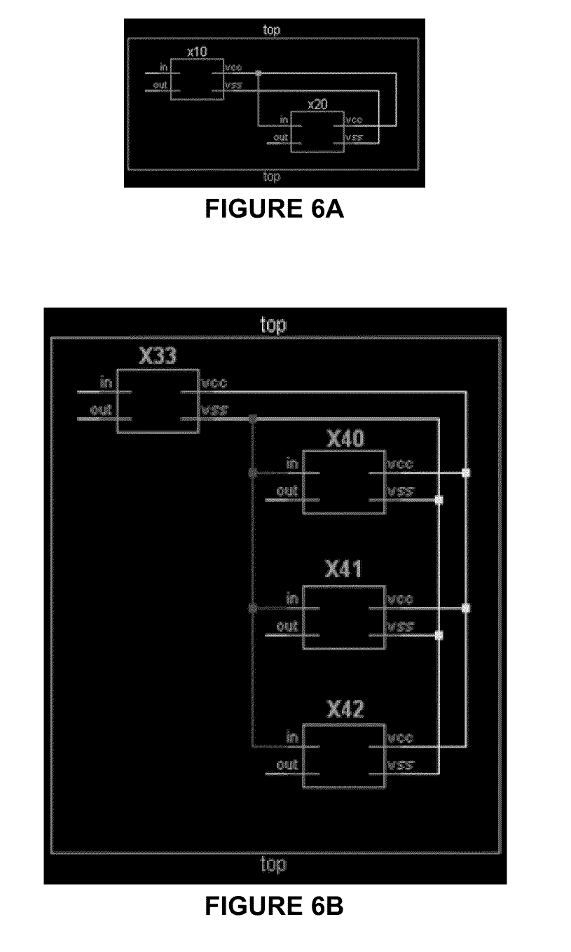

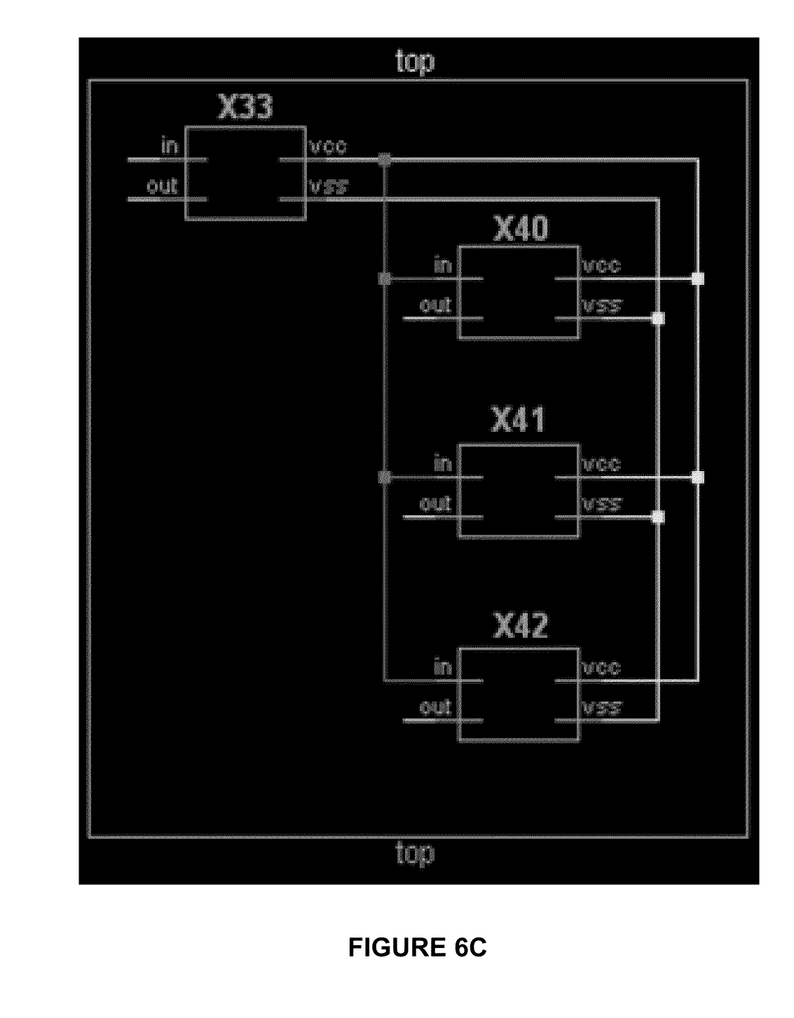

For example, FIG. 6A illustrates an example of an image that may be provided according to various implementations of the invention to graphically show a connection in an original schematic design corresponding to a discrepancy identified in an extracted schematic design. As seen in this figure, the connection between the “in” pin of the device x20 and the pin “vcc” of the device x10 is shown in green, to indicate that this is the correct connection. FIG. 6B then illustrates an example of an image that may be provided according to various implementations of the invention to graphically show the discrepant connection in the extracted schematic design. As seen in this figure, the connection between the “in” pins of the devices x40, x41 and x42 are connected to the pin “vss” of the device x33. This connection is shown in red, to indicate that this is an incorrect connection.

FIG. 6C then illustrates an example of an image that may be provided according to various implementations of the invention to graphically show how the layout design data should be corrected so that the extracted schematic design properly corresponds with the original schematic design. As seen in this figure, the recommended connection between the “in” pins of the devices x40, x41 and x42 are connected to the pin “vcc” of the device x33 is shown in blue. It should be appreciated that various embodiments of the invention can use the device label correspondence information (e.g., transitors T1, T2, and T3 correspond to transistors Ti, Tj, and Tk, respectively) determined by the layout-versus-schematic process (or a corresponding electronic design automation process) in the graphic display of the suggested correction. By using this information, these implementations of the invention allow a user to accurately identify a correction despite differences between the original schematic design and the extracted schematic design, such as different device names, different numbers of corresponding devices between the designs (as illustrated in FIGS. 6A and 6C), etc. Of course, while different colors are used to emphasize different connections in the illustrated example, still other embodiments of the invention may alternately or additionally use other techniques for emphasizing the connections, such as bolding, using dashed lines, etc.

### CONCLUSION

While the invention has been described with respect to specific examples including presently preferred modes of carrying out the invention, those skilled in the art will appreciate that there are numerous variations and permutations of the above described systems and techniques that fall within the spirit and scope of the invention as set forth above. For example, while specific terminology has been employed above to refer to particular electronic design automation processes, it should be appreciated that various examples of the invention may be implemented using any desired combination of electronic design automation processes.

1. (canceled)

2. (canceled)

3. (canceled)

4. (canceled)

5. (canceled)

6. (canceled)

7. A method of identifying an incorrect electrical connection in an extracted schematic design for an electrical circuit, comprising
determining a discrepancy between an original schematic design for an electrical circuit and an extracted schematic design for the electrical circuit;
displaying a first image schematically showing a correct electrical connection corresponding to the discrepancy in a portion of the original schematic design; and
displaying a second image schematically showing an incorrect electrical connection corresponding to the discrepancy in a portion of the extracted schematic design.

8. The method recited in claim 7, further comprising displaying the correct electrical connection corresponding to the discrepancy in the portion of the original schematic design and the incorrect electrical connection corresponding to the discrepancy in the portion of the extracted schematic design each with a different technique.

9. The method recited in claim 7, further comprising displaying a third image schematically showing a correct electrical connection corresponding to the discrepancy in the portion of the extracted schematic design.

10. The method recited in claim 9, further comprising displaying the correct electrical connection corresponding to the discrepancy in the portion of the original schematic design, the incorrect electrical connection corresponding to the discrepancy in the portion of the extracted schematic design, and the correct electrical connection corresponding to the discrepancy in the portion of the extracted schematic design each with a different technique.
